(19) United States
(12) Patent Application Publication
(10) Pub. No.: US 2007/0069224 A1
(43) Pub. Date: Mar. 29, 2007

(54) LIGHT-EMITTING DEVICE, PRODUCTION METHOD THEREOF, AND ELECTRONIC APPARATUS

(75) Inventor: Kozo GYODA, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/465,336

(22) Filed: Aug. 17, 2006

(30) Foreign Application Priority Data
Sep. 26, 2005 (JP) 2005-277284
Jun. 8, 2006 (JP) 2006-159374

(51) Int. Cl. H01L 33/00

(52) U.S. Cl. 257/88

(57) ABSTRACT

In a light-emitting device in which light-emitting elements that emit light having the same color are arrayed in a matrix on a pixel-forming surface of a substrate and the light emitted from the light-emitting elements is emitted from a surface of the substrate opposite to the pixel-forming surface, the light-emitting device includes a recess provided on the side of the light-emitting surface of the substrate and in an area corresponding to the area where the light-emitting elements are provided, and a color filter that selectively transmits the light emitted from the light-emitting elements and that is embedded in the recess.

### BACKGROUND

1. Technical Field

The present invention relates to a light-emitting device, a production method thereof, and an electronic apparatus including the light-emitting device.

2. Related Art

Recently, organic electroluminescent displays (hereinafter referred to as “organic EL displays”) in which a plurality of organic electroluminescent elements (hereinafter referred to as “organic EL elements”) are provided on a substrate have attracted attention because they have features such as a light weight, a high luminance, a wide viewing angle, and a high contrast ratio and are superior to other electro-optical devices. The organic EL elements include a bottom emission organic EL display in which the emitted light is supplied from the reverse side of the substrate having the elements, that is, from the side opposite to a sealing substrate of the light-emitting elements.

Furthermore, in such an organic EL display, a luminescent layer emitting red light, a luminescent layer emitting green light, and a luminescent layer emitting blue light are provided in each display element, and each of the organic EL elements emits light of each color at a predetermined luminance to perform full color display. On the other hand, in another organic EL display, a luminescent layer composed of a single type of an organic material that emits light of a single color (for example, white light) is provided on all the organic EL elements in common, and a color filter is further provided to perform full color display (see, for example, JP-A-2000-12216 and JP-A-2004-111278). The former organic EL display includes an organic EL display produced by an ink-jet method in which light-emitting organic polymer materials that emit red light, green light, or blue light are liquefied and applied on corresponding pixels by jetting.

However, the above known light-emitting organic polymer materials are disadvantageous in that their lifetime is generally short. For example, according to an experimental result, when a known light-emitting organic polymer material emits light at 400 candela, the lifetime is only about 1,000 hours. Furthermore, the light-emitting organic polymer materials are easily denatured by a reaction with water or oxygen. Consequently, it is difficult to commercialize an organic EL display including the light-emitting organic polymer materials.

Furthermore, in the bottom emission organic EL display, since light having each color emitted from the luminescent layer is transmitted through a substrate and emitted to the outside, light having each color is refracted according to the refractive index of the substrate. Accordingly, when the substrate has a large thickness, the optical path length of light refracted on the substrate is increased. Consequently, the refracted light expands to be scattered or absorbed in the substrate, resulting in a decrease in the luminance. In addition, since the scattered light becomes stray light on adjacent pixels, this is not suitable for a highly fine image display. Furthermore, since the stray light on the adjacent pixels causes a color mixture, the color purity is also degraded.

### SUMMARY

An advantage of the invention is that it realizes a light-emitting device that can display highly fine images, embodies the production method thereof, and provides an electronic apparatus including the light-emitting device for display.

According to a first aspect of the invention, in a light-emitting device in which light-emitting elements that emit light having the same color are arrayed in a matrix on a pixel-forming surface of a substrate and the light emitted from the light-emitting elements is emitted from a surface of the substrate opposite to the pixel-forming surface, the light-emitting device includes a recess provided on the side of the light-emitting surface of the substrate and in an area corresponding to the area where the light-emitting elements are provided, and a color filter that selectively transmits the light emitted from the light-emitting elements and that is embedded in the recess.

According to the light-emitting device, light emitted from a luminescent sublayer of each pixel is transmitted through the recess, in which the thickness of the substrate is small, and is incident on a corresponding light selective transmissive layer of the color filter, the pixels emitting light of the same color, e.g., white light. Accordingly, the optical path length of light being transmitted through the substrate is shorter than that of known devices. As a result, the light emitted from the luminescent sublayer is converted to a predetermined color without diffusing in the substrate. Thus, color images having high fineness and highs color purity can be displayed compared with those of known devices. Furthermore, since the optical path length of light being transmitted through the substrate is shorter than that of known devices, the amount of attenuation of the light intensity in the substrate is small. Consequently, color images having high luminance and high contrast can be displayed.

In the light-emitting device, the substrate is preferably composed of glass. It is known that glass materials can be etched using nitric acid or hydrofluoric acid as an etchant. Therefore, when the substrate is composed of glass and nitric acid or hydrofluoric acid is used as the etchant, the recess, in which the thickness of the substrate is small, can be formed on the substrate.

In the light-emitting device, preferably, the luminescent sublayer is mainly composed of low-molecular-weight organic materials. In general, low-molecular-weight organic materials have a lifetime longer than that of polymer materials. Therefore, a light-emitting device in which light is stably emitted and which has a long lifetime can be realized. In addition, a film having a uniform thickness can be easily formed by vapor deposition using such low-molecular-weight organic materials.

In the light-emitting device, the color filter may be fixed with an adhesive in the recess provided on the light-emitting surface of the substrate. In particular, an optical adhesive is preferably used as the adhesive wherein the difference in refractive index between the adhesive and the substrate material of the light-emitting device is small. According to this structure, the light emitted from the luminescent sublayer can perpendicularly travel without being refracted by a medium disposed in a space formed between the substrate and the color filter. Accordingly, images with a high fineness and without light scattering can be displayed. Furthermore, because of high light transmittance, the luminance is not decreased.

In the light-emitting device, selective transmissive layers of the color filter are preferably composed of a pigment. The color filter is used for separating, for example, white light into light of three primary colors, i.e., red, green, and blue. Full color display can be realized by controlling the light intensity in each pixel. In particular, a filter layer including a pigment-based coloring agent has excellent light resistance and can contribute to the display of high-quality images with high color purity.

According to a second aspect of the invention, in a method of producing a light-emitting device in which a functional layer including at least a luminescent sublayer is formed on a pixel-forming surface of a substrate and light emitted from the luminescent sublayer is emitted from a surface of the substrate opposite to the pixel-forming surface, the method includes forming a recess on the light-emitting surface of the substrate, and fitting a color filter by embedding the filter in the recess formed on the light-emitting surface of the substrate.

In the light-emitting device produced by this production method, light emitted from the luminescent sublayer is transmitted through the recess, in which the thickness of the substrate is small, and is incident on the color filter. Therefore, the optical path length of light being transmitted through the substrate is shorter than that of known devices. As a result, the light emitted from each luminescent sublayer is converted to light of a predetermined color without diffusing in the substrate. Thus, color images having high color purity and high fineness can be displayed. Similarly, since the optical path length of light being transmitted through the substrate is shorter than that of known devices, the amount of attenuation of the light intensity in the substrate is small. Consequently, color images having high luminance and high contrast can be displayed.

In the method of producing a light-emitting device, the recess on the light-emitting surface of the substrate is preferably formed by a wet etching process. In particular, when the substrate is composed of glass, a known etchant such as nitric acid or hydrofluoric acid can be used. Alternatively, an etchant prepared by appropriately adding an inorganic acid, an organic acid, a surfactant, or the like to an aqueous solution of a fluoride such as potassium fluoride or sodium fluoride may also be used as the etchant.

According to this method, since a known method of wet etching is employed, the recess, in which the thickness of the substrate is small, can be easily formed. Furthermore, in the etching of the substrate, side faces of the recess formed by etching are continuously connected to the bottom face with curved connecting parts. Consequently, the curvature of the connecting parts formed between the bottom face and the side faces of the recess changes gradually, and thus a sharp change in the thickness can be prevented. As a result, the strength of the connecting part between the bottom face of the recess and the frame of the recess is increased, and the substrate is not easily broken.

In the method of producing a light-emitting device, preferably an adhesive is applied to the recess formed on the side of the light-emitting surface of the substrate, and the color filter is then disposed in the recess. In particular, an optical adhesive is preferably used as the adhesive wherein the difference in refractive index between the adhesive and the substrate material of the light-emitting device is small.

According to this method, the light emitted from the luminescent sublayer is not refracted by a medium disposed at a space formed between the substrate and the color filter. Accordingly, images with a high fineness and without light scattering can be displayed.

According to a third aspect of the invention, an electronic apparatus includes the above-described light-emitting device. Accordingly, an electronic apparatus including a light-emitting device that can display images with high fineness and that has a long lifetime can be provided.

### BRIEF DESCRIPTION OF THE DRAWINGS

The invention will be described with reference to the accompanying drawings, wherein like numbers reference like elements.

FIG. 1 is an exploded perspective view showing an organic EL display of the invention.

FIG. 2 is a cross-sectional view showing the organic EL display of the invention.

FIG. 3 is a schematic view illustrating the operation of the invention.

FIGS. 4A to 4C are process drawings illustrating a production method of the invention.

FIG. 5 is a perspective view of a cell phone to which the invention is applied.

### DESCRIPTION OF EXEMPLARY EMBODIMENTS

Embodiments

The case where an embodiment of the invention is applied to an organic EL display will now be described.

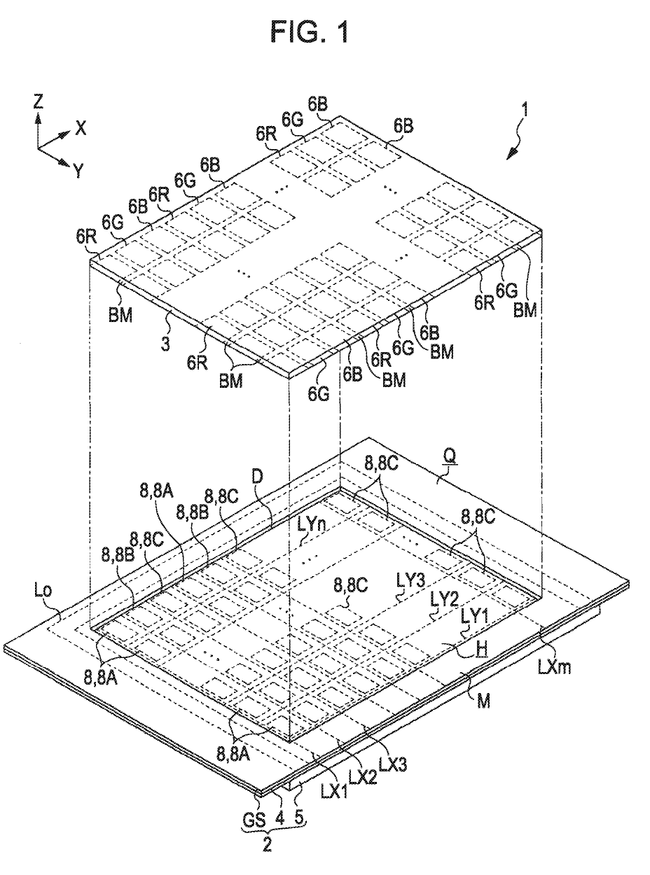

FIG. 1 is an exploded perspective view showing an active matrix organic EL display, which is a light-emitting device of the invention. As shown in FIG. 1, an organic EL display 1 includes a luminescent panel 2 and a color filter 3.

The luminescent panel 2 includes a glass substrate GS, an active-element-forming layer 4; and a sealing plate 5. The active-element-forming layer 4 is provided on a pixel-forming surface N (the lower surface of the GS shown in FIG. 1) of the glass substrate GS, and is sealed with the sealing plate 5. A plurality of pixels 8 (8A, 8B, 8C, and the like) are provided on the active-element-forming layer 4. Light emitted from the plurality of pixels 8 is transmitted through the glass substrate GS and is emitted from a light-emitting surface M (the upper surface of the GS shown in FIG. 1), which is opposite to the pixel-forming surface N. That is, the organic EL display 1 of this embodiment is an organic EL display having the bottom emission structure in which the emitted light is transmitted through a substrate having elements and is emitted from the substrate.

As shown in FIG. 1, the active-element-forming layer 4 is laminated on the pixel-forming surface N of the glass substrate GS. Scanning lines LY1 to LYn, the number of which is n, are provided on the active-element-forming layer 4 in a direction parallel to the row direction (the direction of an arrow X shown in FIG. 1). Data lines LX1 to LXm, the number of which is m, are also provided so as to intersect the scanning lines LY1 to LYn in a direction parallel to the column direction (the direction of an arrow Y shown in FIG. 1). The pixels 8, the number of which is n×m, are arrayed in a matrix at positions corresponding to the intersections of each of the scanning lines LY1 to LYn and each of the data lines LX1 to LXm. The area on which the pixels 8 are arrayed is referred to as a display area H.

Power lines (not shown) for supplying each of the pixels 8 with electric power are provided on the active-element-forming layer 4. A plurality of pixel circuits (not shown) each including a thin-film transistor (TFT) for driving the pixel 8 and the like is provided on the active-element-forming layer 4. A base film, an interlayer insulating film, and the like of this active-element-forming layer 4 are mainly composed of a silicon oxide (SiOₓ) having the same refractive index of light as that of the glass substrate GS.

Rectangular wiring Lo for a common electrode is provided in an area Q (hereinafter referred to as “non-display area”) other than the display area H so as to surround the display area H. A common electric potential is supplied to the wiring Lo for a common electrode. A scanning-line driving circuit (not shown) is provided in the non-display area Q. The scanning-line driving circuit is connected to each of the scanning lines LY1 to LYn and sequentially outputs a scanning signal to each of the scanning lines LY1 to Lyn. Furthermore, a part of the data lines LX1 to LXm extends to the non-display area Q and is connected to an external data-line driving circuit (not shown). A data signal synchronizing the above scanning signal is supplied from the data-line driving circuit to each of the data lines LX1 to LXm.

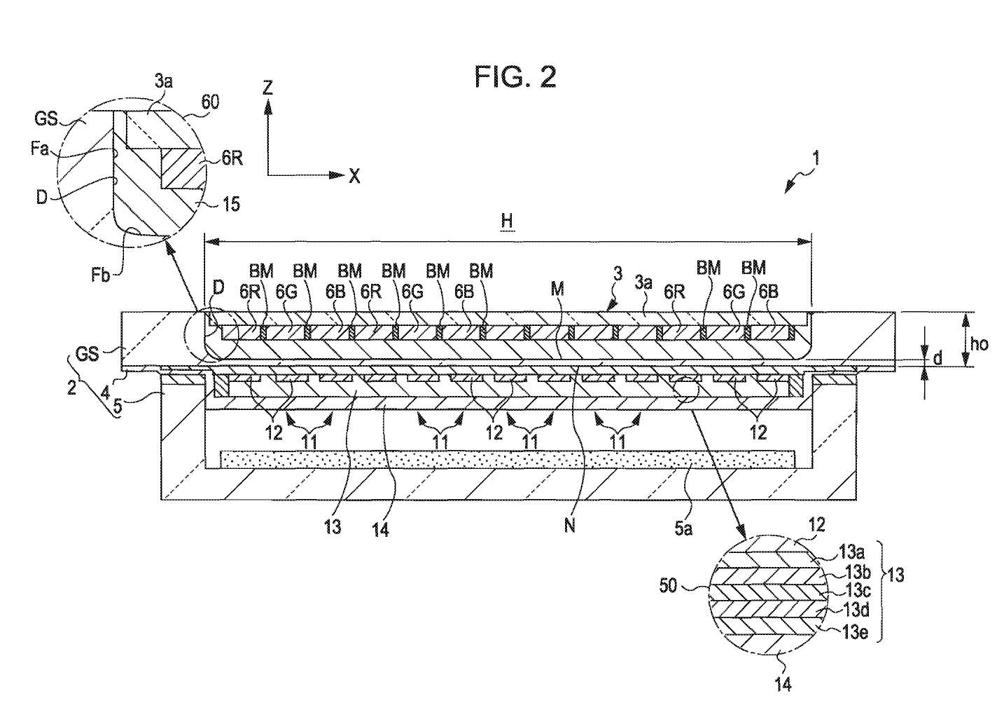

As shown in FIG. 2, pixel electrodes 12, a functional Layer 13 and a common electrode 14 that constitute organic EL elements are provided on the surface of the active-element-forming layer 4. The pixel electrodes 12 are provided in the form of compartments in a matrix so as to correspond to the pixel circuits. The pixel electrodes 12, the number of which is m×n, are provided in this embodiment. The pixel electrodes 12 are composed of a light-transmissive conductive material. In this embodiment, the pixel electrodes 12 are composed of indium tin oxide. A driving current generated in the pixel circuits on the active-element-forming layer 4 is supplied to each of the pixel electrodes 12.

The functional layer 13 is provided on the pixel electrodes 12, and a partition (not shown) for electrical insulation is provided between the pixels. As shown in an enlarged part 50, in the functional layer 13 of this embodiment, a hole injection sublayer 13a, a hole-transporting sublayer 13b, a luminescent sublayer 13c, an electron-transporting sublayer 13d, and an electron injection sublayer 13e are laminated on the pixel electrode 12 in that order. Each of the sublayers 13a to 13e forming the functional layer 13 is composed of an organic material. In particular, the luminescent sublayer 13c is composed of a light-emitting low-molecular-weight organic material that emits white light.

The common electrode 14 is provided on the entire surface of the functional layer 13. The common electrode 14 of this embodiment is composed of a light-reflective magnesium-aluminum alloy (Mg:Al=10:1). A part of the common electrode 14 is connected to the wiring Lo (see FIG. 1) for the common electrode so that a common electric potential is supplied. In the above description, the types of light-emitting organic material, electrode material, and the like significantly affect the luminance of emitted light, the lifetime, and the like of the organic EL elements. However, since the types of materials are not an essence of the invention, a description thereof is omitted.

Thus, in this embodiment, the pixel electrode 12, the common electrode 14, and the luminescent sublayer-containing functional layer 13 provided between the electrodes form an organic EL element 1l. The organic EL element 11 and the pixel circuit (not shown) that includes a thin-film transistor and that supplies the organic EL element 11 with a driving current forms a pixel 8 (8A, 8B, or 8C). A current is supplied between the pixel electrode 12 and the common electrode 14. Thereby, the organic EL element 11 emits white light. In this case, the light emitted in the negative direction of the Z axis is reflected on the common electrode 14 in the positive direction of the Z axis. Accordingly, the white light emitted from the organic EL element 11 is transmitted through the pixel electrode 12, the active-element-forming layer 4, and the glass substrate GS, and is emitted from the light-emitting surface M.

The functional layer 13 and the common electrode 14 are sealed with the sealing plate 5 having a hollow structure. The sealing plate 5 is a molded glass container or a glass container prepared by etching so as to have a recess. The sealing plate 5 is fixed to the outer periphery adjacent to the pixel-forming surface N of the glass substrate GS by bonding with an adhesive. A desiccating agent 5a such as silica gel is filled inside the hollow part of the sealing plate 5 to prevent the functional layer 13 from being denatured by moisture.

A substrate recess D having an area corresponding to the display area H is provided on the light-emitting surface M of the glass substrate GS. The recess D is formed by wet etching the glass substrate using known nitric acid or hydrofluoric acid as an etchant. The recess D is formed by etching so that the thickness d of the glass plate at the bottom of the recess is 25 μm. It is generally known that a glass having a thickness of 25 μm can maintain its shape. In this embodiment, the thickness d of the glass substrate GS corresponds to a thickness of an ultrathin film. Accordingly, in this embodiment, the glass plate having a thickness ho of 500 μm is used, and the recess D having a depth of 475 μm is formed.

The color filter 3 includes a light-transmissive filter substrate 3a. A black matrix BM for light-shielding is provided on the filter substrate 3a in the form of a grid. Transparent colored layers 6R (hereinafter referred to as “red colored layers”) that are colored with red, transparent colored layers 6G (hereinafter referred to as “green colored layers”) that are colored with green, and transparent colored layers 6B (hereinafter referred to as “blue colored layers”) that are colored with blue are provided on spaces surrounded by the black matrix BM provided in a grid shape.

The red colored layers 6R are light selective transmissive layers that selectively transmit only red light from the white light emitted from the pixel 8. Each of the red colored layers 6R is disposed so as to face a corresponding first pixel 8A. The green colored layers 6G are light selective transmissive layers that selectively transmit only green light from the white light emitted from the pixel 8. Each of the green colored layers 6G is disposed so as to face a corresponding second pixel, 8B. The blue colored layers 6B are light selective transmissive layers that selectively transmit only blue light from the white light emitted from the pixel S. Each of the blue colored layers 6B is disposed so as to face a corresponding third pixel 8C. Three pixels 8 (8A, 8B, and 8C) composed of a set of the red colored layer 6R, the green colored layer 6G, and the blue colored layer 6B that are adjacent to each other along the row direction (the direction of the X axis shown in FIG. 1) form a set of color pixels. In this embodiment, each of the colored layers 6R, 6G, and 6B are composed of a pigment.

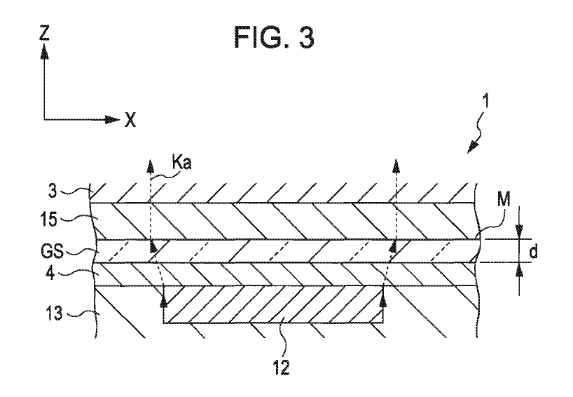

The operations and advantages of the organic EL display according to the invention, which have become evident by the above description, will now be described with reference to FIG. 3. As shown In FIG. 3, when the luminescent sublayer 13c in the functional layer 13 emits light, the resulting white light Ka is transmitted through the pixel electrode 12 and is incident on the active-element-forming layer 4. In this case, the light Ka transmitted through the pixel electrode 12 is refracted on the interface between the pixel electrode 12 and the active-element-forming layer 4 according to the difference in the materials between the pixel electrode 12 and the active-element-forming layer 4. In general, indium tin oxide used for the pixel electrode 12 has a high refractive index, whereas a silicon oxide used for the active-element-forming layer 4 has a low refractive index. Consequently, the light traveling from the side of the pixel electrode 12 to the active-element-forming layer 4 is bent in a direction in which the light is diffused.

The light Ka incident on the active-element-forming layer 4 is then incident on the glass substrate GS. Since the active-element-forming layer 4 and the glass substrate GS are composed of the same material (silicon oxide), the refractive indices thereof are substantially the same. Therefore, the light Ka transmitted through the active-element-forming layer 4 is incident on the glass substrate without refraction.

The light Ka incident on the glass substrate GS is then incident on the color filter 3 through an optical adhesive 15. When the light Ka transmitted through the glass substrate GS is incident on the optical adhesive 15, the light Ka transmitted through the glass substrate GS is refracted on the interface with the optical adhesive 15 because the refractive indices are different according to the materials of the glass substrate GS and the optical adhesive 15. The refractive index of the optical adhesive 15 and the refractive index of the color filter 3 are controlled so as to be substantially the same. Consequently, when the light Ka transmitted through the optical adhesive 15 is incident on the color filter 3, the light Ka is incident on the color filter 3 without refraction.

As described above, in the organic EL display 1, the light Ka emitted from the luminescent sublayer 13c of the functional layer 13 is refracted on the interface between the pixel electrode 12 and the active-element-forming layer 4 and the interface between the glass substrate GS and the optical adhesive 15 according to their refractive indices. Therefore, the optical path of the light Ka being transmitted through the glass substrate GS diverges in the direction of the X axis (horizontal direction) shown in FIG. 3. However, the glass substrate GS of this embodiment has a thickness d of 25 μm, which is significantly small. As a result, the optical path length of the light Ka being transmitted through the glass substrate GS is short, and thus the degree of divergence of the light Ka can be decreased.

Accordingly, in the organic EL display 1 of this embodiment, the light Ka emitted from each luminescent sublayer 13c is incident toward the red, green, and blue colored layers 6R, 6G, and 6B of the color filter 3 disposed at corresponding positions without excessively diverging. As a result, an image displayed on the color filter 3 has high color purity without a color mixture and is suitable for highly fine image display.

In addition, since the optical path length of the light Ka being transmitted through the glass substrate GS is short, the amount of attenuation of the light intensity in the glass substrate GS is smaller than that of the case where the light is transmitted through a known glass substrate R. Consequently, a decrease in the luminance and a decrease in the contrast ratio can be suppressed.

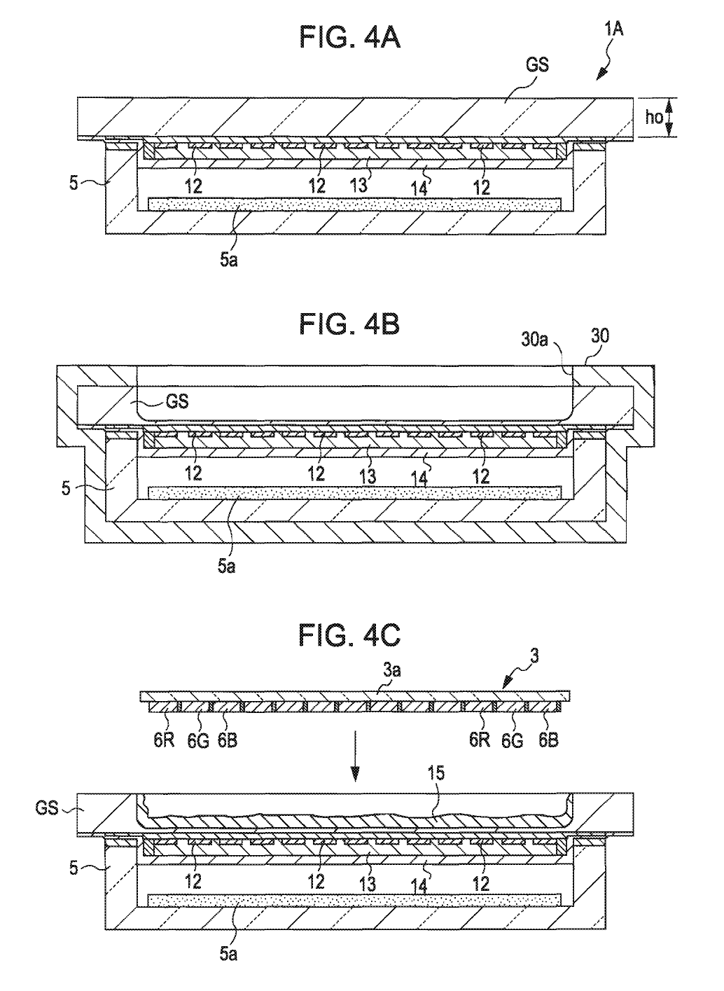

A method of producing the organic EL display 1 having the above structure will be briefly described. A part that is particularly associated with the invention will be described with reference to FIGS. 4A to 4C.

First, a glass substrate GS having a thickness ho of 500 μm, is prepared as a substrate for forming elements. The glass substrate GS is washed with a solvent for cleaning, a pure water spray, or the like and then dried. Subsequently, a base insulating film, a silicon thin-film, an interlayer insulating film, metal conductive layers for wiring and electrodes, and the like are formed on the pixel-forming surface N of the glass substrate GS by a known method such as chemical vapor deposition (CVD), sputtering, or vapor deposition. Processes such as patterning, heat treatment, introduction of impurity ions into the silicon film are performed for each of the thin-films to form desired driving transistors (TFTs), capacitive elements, the scanning lines LY1 to LYn, the data lines LXl to LXm, and the like. These are steps of forming active elements and their peripheral circuits and are very complex. However, since these steps are not an essence of the invention, please refer to other documents, materials, and the like for details.

Subsequently, the entirety of the active-element-forming layer 4 is covered with an insulating layer, contact holes for connecting to electrodes of the transistors are formed, and indium tin oxide (ITO) is then deposited by vapor deposition or the like on the entire surface. Subsequently, the ITO is patterned so as to have a desired shape. Thus, a plurality of pixel electrodes 12 is formed in a matrix array in a predetermined area (display area H) on the glass substrate GS.

Subsequently, low-molecular-weight organic materials constituting the hole injection sublayer 13a, the hole-transporting sublayer 13b, the luminescent sublayer 13c, the electron-transporting sublayer 13d, and the electron injection sublayer 13e are sequentially deposited on the pixel electrodes 12 to form the functional layer 13. When a material formed as a layer having a plurality of functions is used, all the above sublayers need not be formed.

Furthermore, the common electrode 14 is formed on the entire surface of the functional layer 13 by depositing, for example, a magnesium-aluminum alloy (Mg:Al=10:1). Thereby, pixels 8 composed of a plurality of organic EL elements are formed on the glass substrate GS.

The sealing plate 5 including the desiccating agent 5a is then fixed to the outer periphery of the glass substrate GS by bonding with a predetermined adhesive. FIG. 4A shows a cross-section of an organic EL display 1A after the above steps have been performed.

Subsequently, the whole organic EL display 1A is dipped in a bath filled with a photoresist, and the resist is dried. As shown in FIG. 4B, a photomask having an opening 30a corresponding to the display area H is disposed on the light-emitting surface side of the glass substrate GS of the organic EL display 1A. The resist is then exposed and developed to remove the resist on the opening 30a. As a result, a resist mask 30 remains around the organic EL display 1A. Alternatively, a mask may be disposed on the opening 30a in advance, and the resist may then be applied by spraying, brush coating, or the like.

Wet etching is then performed using a known etchant such as hydrofluoric acid. Any aqueous solution that can dissolve glass can be used as the etchant. Examples thereof include etchants prepared by appropriately adding an inorganic acid, an organic acids a surfactant, or the like to an aqueous solution of a fluoride such as potassium fluoride or sodium fluoride. In order to increase the etching speed, a temperature-controlled aqueous solution is also often used. In the etching, when a plurality of organic EL displays 1A are simultaneously processed, a cassette batch dipping process is preferably performed. When a single organic EL display 1A is processed, a shower process is preferably performed in the etching. In this step, a recess is formed in the opening 30a of the organic EL display 1A. The etching is continued until the thickness of the bottom of the recess is decreased to 25 μm (recess forming step).

Regarding the shape of the recess, as shown in an enlarged part 60 of FIG. 2, a side face Fa and the bottom face Fb of the recess D form a continuous surface the curvature of which continuously changes after the wet etching. Furthermore, as shown in the figure, the recess is disposed inside the adhesion area between the glass substrate GS on which light-emitting elements are formed and the sealing plate 5. According to this shape and structure, cracks or the like are not easily formed on the connecting part wherein the thickness is varied.

Subsequently, the resist mask 30 is removed from the glass substrate GS, and the glass substrate GS is then washed. The optical adhesive 15 having an adjusted refractive index is applied to the recess D (see FIG. 4C). The color filter 3, which is separately produced, is fitted in the recess D of the display. Thereby, the color filter 3 is fixed in the recess D of the glass substrate GS (filter-fitting step). A pigment-containing color filter produced by a known production process is most suitably used as the color filter 3. In an example of a recent color filter, a glass plate is used as the filter substrate 3a, the black matrix BM is formed on the filter substrate 3a in a grid shape, and the red, green, and blue colored layers 6R, 6G, and 6B are then formed by an ink-jetting method in compartment areas formed by the black matrix BM. As described above, the organic EL display 1 of the invention is completed.

According to this embodiment, the invention has the following operations and advantages.

(1) According to this embodiment, the recess D is provided on the light-emitting surface M of the glass substrate GS so as to correspond to the display area H. Accordingly, when the light Ka emitted from the luminescent sublayer 13c is refracted on the active-element-forming layer 4, the refracted light is transmitted through the bottom of the recess of the glass substrate GS and is emitted to the outside, the optical path length of the light being transmitted through the glass substrate GS is short. Therefore, the degree of divergence of the light Ka in the horizontal direction can be decreased. That is, scattering of the light emitted from each pixel can be suppressed.

(2) According to this embodiment, the light Ka emitted from the luminescent sublayer 13c is transmitted through the bottom of the recess of the glass substrate GS having a small thickness and emitted to the outside. Therefore, the amount of light absorbed by the glass substrate GS can be decreased, thereby an image can be displayed with a high luminance while the attenuation of the luminance of emitted light is suppressed.

(3) Furthermore, according to this embodiment, the divergence in the horizontal direction of the light Ka being transmitted through the glass substrate GS can be decreased. Therefore, the light Ka emitted from a predetermined luminescent sublayer 13c can be incident perpendicularly on the red, green, or blue colored layer 6R, 6G, or 6B of the color filter 3 disposed at an appropriate position. Consequently, a high-color-purity image without a color mixture can be displayed. Furthermore, since the color mixing does not easily occur, this embodiment can also contribute to the realization of a high-fineness display.

(4) According to this embodiment, the color filter 3 is bonded to the glass substrate GS with the optical adhesive 15 having the same refractive index as the color filter 3 and the glass substrate GS. Accordingly, the light Ka being transmitted through the optical adhesive 15 is incident on the color filter 3 without reflection. As a result, the diffusion in the horizontal direction of the light Ka incident on the color filter 3 can be minimized.

(5) According to this embodiment, the luminescent sublayer 13c of the organic EL functional layer 13 is composed of a low-molecular-weight organic material. Since the lifetime of the luminescent sublayer 13c composed of such a low-molecular-weight organic material is long, the organic Eli display 1 having a long lifetime can be realized.

(6) According to this embodiment, the recess D, in which the thickness of the glass substrate GS is small, is formed by wet etching. Accordingly, the thickness of a connecting part formed by a side face Fa and the bottom face Fb of the recess D is gradually changed. Furthermore, the recess D is disposed inside the adhesion areas between the glass substrate GS on which light-emitting elements are formed and the sealing plate 5. This structure can further increase the strength of the connecting parts. Accordingly, the generation of cracks can be suppressed in thee recess D and the peripheral part of the recess D, and thus the glass substrate GS that is not easily broken can be provided. In particular, this structure is advantageous in that breaking of the substrate can be prevented, for example, during transfer in the production process.

(7) According to this embodiment, each of the red, green, and blue colored layers 6R, 6G, and 6B of the color filter 3 is composed of a pigment. Accordingly, a display device having a high light resistance and a long lifetime can be provided. Furthermore, since the production of the color filter can be completely separated from the production of light-emitting elements, the production method is not complicated. Accordingly, this production method provides a high yield.

(8) According to this embodiment, a glass substrate is provided between the color filter and the light-emitting elements. Therefore, contaminants from the color filter, oxygen, moisture, and the like can be blocked, and a decrease in the lifetime of the light-emitting elements can be prevented.

Electronic Apparatus

The organic EL display 11 can be used for various electronic apparatuses such as mobile personal computers, cell phones, and digital cameras, and electronic apparatuses for automobiles. Recently, an application of the organic EL display 1 to a gauge panel of the dashboard of automobiles has been expected. An example of a portable apparatus including the organic EL display 1 described in the above embodiment will now be described.

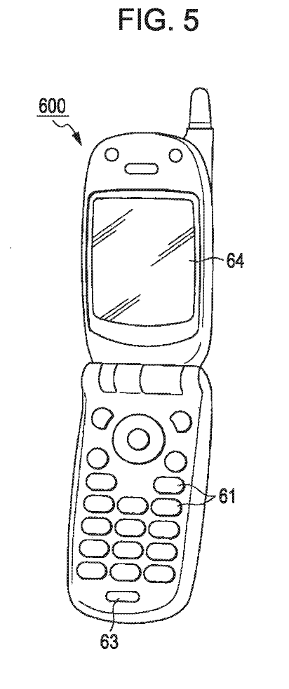

FIG. 5 is a perspective view of a cell phone 600. The cell phone 600 includes a display unit 64 including the organic EL display 1 described in the above embodiment, a plurality of operation buttons 61, a microphone part 63, and the like. The display unit 64 includes a display with high color purity, high luminance, and high fineness, which is described in the above embodiment. Therefore, the cell phone 600 including a display with excellent visibility can be realized.

Modifications of the Invention

The invention can be modified as follows and embodied.

(1) In the above embodiment, the recess D of the glass substrate GS has a thickness d of 25 μm, which is a thickness of an ultrathin glass film. The invention is not limited thereto. The thickness of the glass may be determined according to needs of the display. The thickness of the glass is preferably further decreased in consideration of required specifications such as the production yield and the degree of fineness required during use. At the time of embedding of the color filter, since the recess is reinforced, a problem of reduction in strength does not occur.

(2) In the above embodiment, a glass substrate is used in the organic EL display. Alternatively, the embodiment can be applied to a substrate other than a glass substrate. For example, the substrate may be composed of a light-transmissive resin. In essence, it is sufficient that a recess can be formed on the lightemitting surface of the substrate so that the distance between the luminescent layer and the color filter is decreased, and the refractive scattering of light can be suppressed therebetween. When a resin is used as the substrate, the resin can be molded as a substrate having a recess in advance.

(3) In the above embodiment, the recess is formed by wet etching, but the method is not limited thereto. Alternatively, the recess may be formed by dry etching using plasma.

(4) In the above embodiment, the luminescent sublayer 13c is composed of a low-molecular-weight organic material that emits white light, but the invention is not limited thereto. Alternatively, the luminescent sublayer 13c may be composed of a low-molecular-weight organic material that emits light other than white light. In such a case, the same advantages as those in the above embodiment can be obtained. White light is separated into light of red, green, and blue, which are the three primary color components of light, to realize full color display. Alternatively, when a source of light emission other than one of white light is used, the development of a missing color among the three primary colors can be achieved by inserting a color conversion layer to achieve full color display.

(5) In the production method of the above embodiment, the sealing plate 5 for sealing the functional layer 13 is formed on the side of the pixel-forming surface N of the glass substrate GS, and the recess D is then formed on the glass substrate GS. Alternatively, the recess D may be formed on the light-emitting surface M of the glass substrate GS in advance, and the active-element-forming layer 4 may then be formed on the side of the pixel-forming surface N.

(6) In the above embodiment, each of the hole injection sublayer 13a, the hole-transporting sublayer 13b, the luminescent sublayer 13c, the electron-transporting sublayer 13d, and the electron injection sublayer 13e that constitute the functional layer 13 is composed of a low-molecular-weight organic material, but the invention is not limited thereto. Although the problem of the lifetime still remains, each of the organic layers may be composed of an organic polymer material. In such a case, each organic material may be dissolved or dispersed in a predetermined solvent, and the light-emitting part of the corresponding pixel may be formed by discharging the resulting liquid by an ink-jetting method.

(7) In the above embodiment, the functional layer 13 includes five sublayers, i.e., the hole injection sublayer 13a, the hole-transporting sublayer 13b, the luminescent sublayer 13c, the electron-transporting sublayer 13d, and the electron injection sublayer 13e, but the invention is not limited to this structure. Some of the sublayers 13a to 13e may have a plurality of functions.

(8) In the above embodiment, the recess is formed on the glass substrate GS by etching. Alternatively, the whole glass substrate GS may be additionally processed by etching to form an ultrathin substrate. A color filter that is separately prepared may be bonded on the entirety of the substrate. Alternatively, the color filter may be laminated directly on the ultrathin glass substrate after etching.

What is claimed is:

1. A light-emitting device in which light-emitting elements that emit light having the same color are arrayed in a matrix on a pixel-forming surface of a substrate and the light emitted from the light-emitting elements is emitted from a surface of the substrate opposite to the pixel-forming surface, the light-emitting device comprising:
a recess provided on the side of the light-emitting surface of the substrate and in an area corresponding to the area where the light-emitting elements are provided; and
a color filter that selectively transmits the light emitted from the light-emitting elements and that is embedded in the recess.

2. The light-emitting device according to claim 1, wherein the substrate is composed of glass.

3. The light-emitting device according to claim 1, wherein the light-emitting elements are mainly composed of a low-molecular-weight organic material.

4. The light-emitting device according to claim 1, wherein the color filter is fixed with an adhesive in the recess provided on the light-emitting surface of the substrate.

5. The light-emitting device according to claim 1, wherein selective transmissive layers of the color filter are composed of a pigment.

6. A method of producing a light-emitting device in which a functional layer including at least a luminescent sublayer is formed on a pixel-forming surface of a substrate and light emitted from the luminescent sublayer is emitted from a surface of the substrate opposite to the pixel-forming surfaces the method comprising:
forming a recess on the light-emitting surface of the substrate; and
fitting a color filter by embedding the filter in the recess formed on the light-emitting surface of the substrate.

7. The method of producing a light-emitting device according to claim 6, wherein the recess is formed by a wet etching process.

8. The method of producing a light-emitting device according to claim 6, wherein an adhesive is applied to the recess formed on the side of the light-emitting surface of the substrate, and the color filter is then disposed in the recess.

9. An electronic apparatus comprising the light-emitting device according to claim 1.
